(19) United States
(12) Patent Application Publication
(10) Pub. No.: US 2018/0131394 A1
(43) Pub. Date: May 10, 2018

(54) DATA PROCESSING SYSTEM AND DATA PROCESSING APPARATUS

(71) Applicant: FUJITSU LIMITED, Kawasaki-shi (JP)

(72) Inventor: Ichiro yokokura, Sano (JP)

(73) Assignee: FUJITSU LIMITED, Kawasaki-shi (JP)

(21) Appl. No.: 15/797,531

(22) Filed: Oct. 30, 2017

(30) Foreign Application Priority Data
Nov. 4, 2016 (JP) 2016-216525

(51) Int. Cl. H03M 13/29; H03M 13/09

(52) U.S. Cl. CPC H03M 13/2906; H03M 13/098

(57) ABSTRACT

A data processing system includes a first arithmetic-circuit to perform a first error-correction-code operation on an input bit-string so as to generate a first bit-string including the input bit-string and a result of the first error-correction-code operation, a parity arithmetic-circuit to acquire a parity bit of the first bit-string, a second arithmetic-circuit to perform a second error-correction-code operation on a second bit-string including the first bit-string and the parity bit, a specifying-circuit to specify a number of at most N-bit-error and an error position in the second bit-string, based on an operation result of the second error-correction-code operation on the second bit-string, a parity check-circuit to perform a parity check on the second bit-string, and a control-circuit to detect a N+1-bit-error in the first bit-string when the number of bit error is N and a result of the parity check indicates that there is an error.

### CROSS-REFERENCE TO RELATED APPLICATION

This application is based upon and claims the benefit of priority of the prior Japanese Patent Application No. 2016-216525, filed on Nov. 4, 2016, the entire contents of which are incorporated herein by reference.

### FIELD

The embodiments discussed herein are related to a data processing system and a data processing apparatus for detecting bit errors.

### BACKGROUND

As the Internet traffic increases, the transmission speed of a network transmission device and the capacity of transmission data are being increased. Meanwhile, in terms of maintenance and operation, it is required to lower the voltage in order to reduce the size of the transmission device and lower the power consumption. Thus, in the development of a large-scale integration (LSI), and a field-programmable gate array (FPGA) mounted on the network transmission device, a process miniaturization is being progressed. The process miniaturization refers to reducing the gate width, gate interval, line width, or line interval of a transistor mounted on the LSI and the FPGA.

As the process miniaturization is being progressed, the possibility of an occurrence of a soft error such as a bit error increases in a random access memory (RAM) mounted inside the LSI and the FPGA. The soft error in the RAM may cause system malfunction or the like. The bit error also occurs due to an influence such as a noise or the like even during a signal transmission. For the detection and correction of the bit error, for example, an error correction code is used. As an example of the error correction code used for detecting and correcting the bit error, a Hamming code, and a BCH code may be exemplified.

In the error detection and correction using the error correction code, a code generation processing for generating an error code, and a code check processing for detecting and correcting an error by the error code are performed. For example, in the code generation processing using a Hamming code or a BCH code, an operation using a predetermined polynomial is performed on data constituting a bit string of an input digital signal. In the present specification, data obtained as an operation result of an encoding function using the predetermined polynomial is called a codeword. A bit error may occur when the input bit string and codeword are stored in, for example, a primary storage memory (RAM), or transmitted to a network.

In the code check processing using a Hamming code or a BCH code, an operation using a predetermined polynomial is performed again on the input bit string and codeword which are read from the primary storage memory (RAM) or received from the network. The polynomial used at this time is a polynomial having a predetermined relationship with a polynomial used for the input bit string. The data obtained as the operation result is called a syndrome. The presence or absence of an error, and the location of an error are indicated by the syndrome.

By inverting a bit at a position specified by a Hamming code operation or a BCH code operation and correcting an error, it is possible to reduce the influence due to a soft error or a transmission noise occurring in the RAM. In the Hamming code operation, a 1-bit error may be detected and corrected. In the BCH code operation, an error of two or more bits may be detected and corrected.

Related technologies are disclosed in, for example, Japanese Laid-Open Patent Publication No. 61-139846, and International Publication Pamphlet No. WO 1996/038922.

### SUMMARY

According to an aspect of the invention, a data processing system includes a first arithmetic circuit configured to perform a first error correction code operation on an input bit string so as to generate a first bit string including the input bit string and a result of the first error correction code operation, a parity arithmetic circuit configured to acquire a parity bit of the first bit string, a second arithmetic circuit configured to perform a second error correction code operation on a second bit string including the first bit string and the parity bit, a specifying circuit configured to specify a number of at most N-bit error and an error position in the second bit string, based on an operation result of the second error correction code operation on the second bit string, wherein N is an integer larger than 0, a parity check circuit configured to perform a parity check on the second bit string, and a control circuit configured to detect a N+1-bit error in the first bit string when the number of bit error specified by the specifying circuit is N and a result of the parity check indicates that there is an error.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a view illustrating an example of an error detection and correction processing using a Hamming code operation;

FIG. 2 is a view illustrating an example of an error detection and correction processing using a BCH code operation in which a 2-bit error is detected and corrected;

FIG. 3 is a view illustrating an example of an error detection and correction processing using a BCH code operation, in which a 3-bit error is detected and corrected;

FIG. 4 is an example of an error check unit that executes an error detection and correction processing according to a first embodiment;

FIG. 5A is a view illustrating an example of a flow of a processing of the error check unit according to the first embodiment;

FIG. 5B is a view illustrating an example of a flow of a processing of the error check unit according to the first embodiment;

FIGS. 6A to 6C are an example of an error determination table;

FIG. 7 is a view illustrating a relationship between A, B, C, and D in an error detection and correction using a 2-bit error detectable and correctable BCH code operation, on the premise that an error of 2 bits at maximum occurs;

FIG. 8 is a view illustrating a relationship between A, B, C, and D in an error detection and correction using a 2-bit error detectable and correctable BCH code operation, on the premise that an error of 3 bits at maximum occurs;

FIG. 9 is a view illustrating a relationship between A, B, C, and D in an error detection and correction by the error check unit according to the first embodiment, on the premise that an error of 3 bits at maximum occurs;

FIG. 10 is a view illustrating a relationship between A, B, C, and E in an error detection and correction by the error check unit according to the first embodiment, on the premise that an error of 3 bits at maximum occurs;

FIG. 11 is an example of a flow chart of a process of a controller of the error check unit according to the first embodiment;

FIGS. 12A to 12E are views illustrating an example of a circuit configuration of a polynomial and a polynomial arithmetic unit in a specific example;

FIG. 13A is a view illustrating an example of a processing when a 2-bit soft error occurs in a RAM of the error check unit according to the specific example;

FIG. 13B is a view illustrating an example of a processing when a 2-bit soft error occurs in the RAM of the error check unit according to the specific example;

FIG. 14A is a view illustrating an example of a processing when a 3-bit soft error occurs in the RAM of the error check unit according to the specific example;

FIG. 14B is a view illustrating an example of a processing when a 3-bit soft error occurs in the RAM of the error check unit according to the specific example;

FIG. 15 is a view illustrating an example of a processing when a 3-bit soft error occurs in the RAM of the error check unit according to the specific example;

FIG. 16 is an example of a table illustrating a relationship between various algorithms of an error correction code and the number of usages of a lookup table;

FIG. 17 is a view illustrating an example of a hardware configuration of a network device mounted with the error check unit according to the first embodiment;

FIG. 18 is an example of a block diagram of an FPGA within a network device; and

FIG. 19 is an example of a block diagram of a frame reception unit.

### DESCRIPTION OF EMBODIMENTS

As the number of error detectable bits increases, the number of polynomials, the number of tables used to specify an error position from a syndrome or the like may be increased, and a circuit scale may be increased.

Hereinafter, embodiments of a technology capable of suppressing an increase of a circuit scale and increasing the number of detectable bit error will be described with reference to the accompanying drawings. The configuration of the following embodiments is exemplary only and the present disclosure is not limited to the configuration of the embodiments.

### First Embodiment

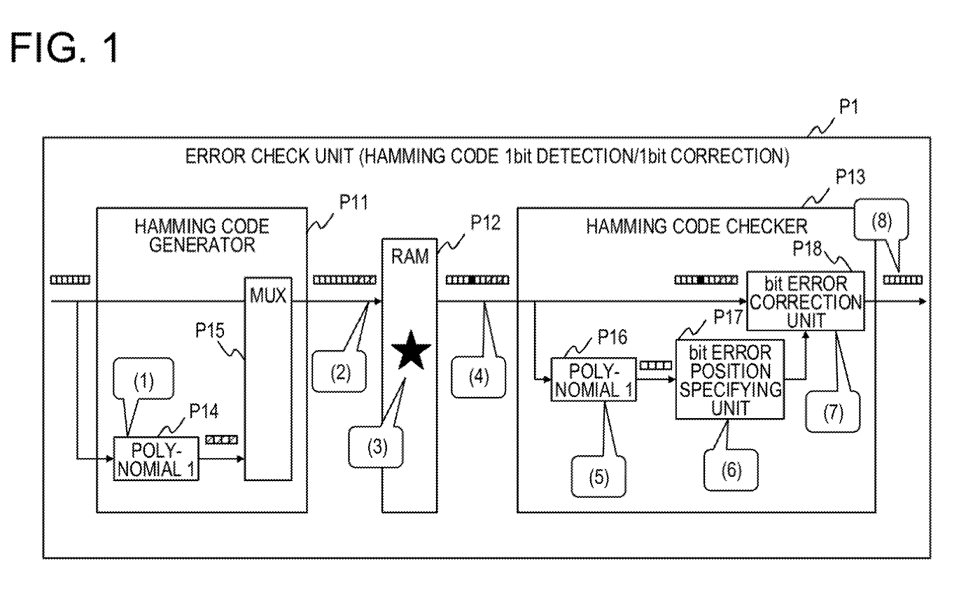

FIG. 1 is a view illustrating an example of an error detection and correction processing using a Hamming code operation. An error check unit P1 is an example of a circuit that executes the error detection and correction processing using a Hamming code operation. The error check unit P1 is formed by a combination of a RAM, a flip-flop, a lookup table, an arithmetic circuit such as a gate executing arithmetic operations, product-sum operations or the like, within, for example, an FPGA.

The error check unit P1 includes a Hamming code generator P11, a RAM P12, and a Hamming code checker P13. The Hamming code generator P11 performs a Hamming code operation on input data, and encodes the data. The Hamming code generator P11 includes a polynomial arithmetic unit P14 and a multiplexer (indicated as MUX in the drawing) P15. The Hamming code checker P13 performs a Hamming code operation on encoded data read from the RAM P12, and performs an error detection and an error correction. The Hamming code checker P13 includes a polynomial arithmetic unit P16, a bit error position specifying unit P17, and a bit error correction unit P18.

The error detection and correction processing using the Hamming code operation by the error check unit P1 is performed as, for example, following steps (1) to (8). An input bit string that is the input data is called a report value.

(1) A report value is input to the polynomial arithmetic unit P14. The polynomial arithmetic unit P14 performs a Hamming code operation using a polynomial 1 on the report value. The polynomial 1 is determined in advance according to the code length of a Hamming code. For example, in association with the Hamming code operation with a code length of 7 bits and a report value of 4 bits, the polynomial arithmetic unit P14 performs an operation in which 3 bits of zero (0) are added to the end of the report value to make the report value as a bit string of 7 bits, a polynomial with the bit string as a coefficient is divided by the polynomial 1, and the remainder is set as an operation result. Hereinafter, the operation result of the polynomial arithmetic unit P14 is called a codeword.

(2) The report value and the codeword are input to the multiplexer P15. The multiplexer P15 adds the codeword to the end of the report value, and the set of the codeword and the report value is written on the RAM P12. Hereinafter, the bit string output from the Hamming code generator P11 will be referred to as a transmission word. In FIG. 1, the transmission word corresponds to a set of the report value and the codeword.

(3) It is assumed that a bit error has occurred by a soft error in the RAM P12. It is assumed that due to the bit error, a bit error of 1 bit has occurred in the set of the report value and the codeword.

(4) The set of the report value and the codeword is read from the RAM P12, and is input to the Hamming code checker P13. Hereinafter, the bit string input to the code checker will be referred to as a received word. In FIG. 1, the received word corresponds to a set of the report value and the codeword read from the RAM P12.

(5) The received word is input to the polynomial arithmetic unit P16. The polynomial arithmetic unit P16 performs a Hamming code operation using a polynomial 1 on the received word. The polynomial 1 used in the polynomial arithmetic unit P16 is the same as the polynomial 1 used in the polynomial arithmetic unit P14. Specifically, the polynomial arithmetic unit P16 performs an operation in which a polynomial with the received word as a coefficient is divided by the polynomial 1, and the remainder is set as an operation result. The operation result obtained by the polynomial arithmetic unit P16 will be referred to as a syndrome.

(6) The syndrome is input to the bit error position specifying unit P17. An error determination table (not illustrated) that stores a correspondence between a value of a syndrome and a position of a bit error of 1 bit is stored in a lookup table. The bit error position specifying unit P17 specifies the position of the bit error of 1 bit in the received word based on the value of the input syndrome and the error determination table. The specified position of the bit error in the received word is input to the bit error correction unit P18.

(7) The received word and the position of the bit error in the received word are input to the bit error correction unit P18. The bit error correction unit P18 inverts the bit at the position of the bit error in the received word, and corrects the bit error.

(8) An error-corrected bit string is output. Hereinafter, the bit string output from the error correction unit will be referred to as a decoded word.

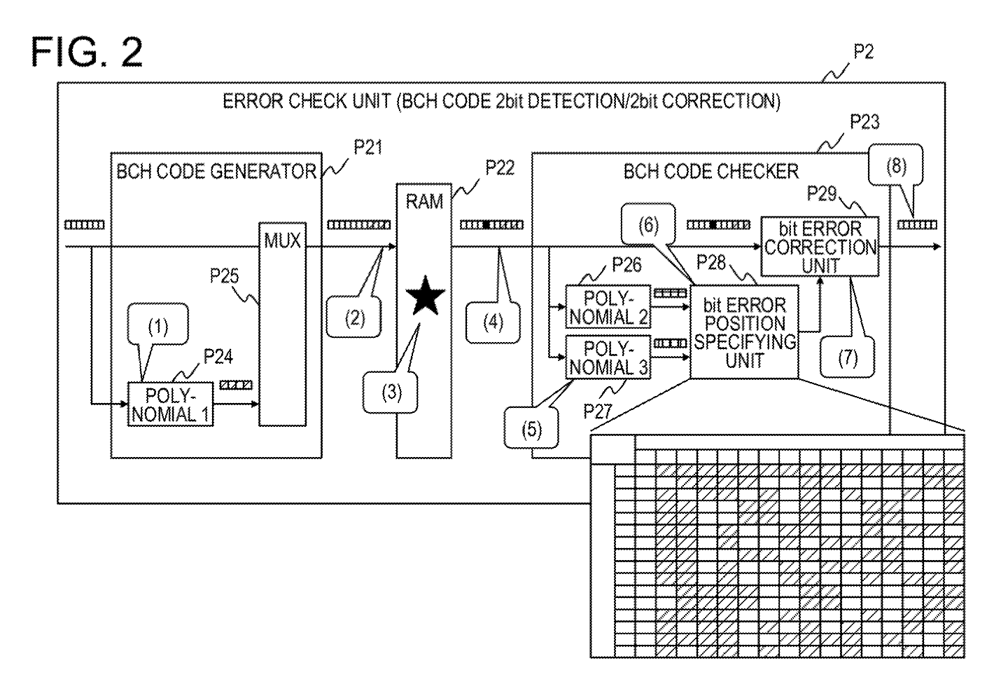

FIG. 2 is a view illustrating an example of an error detection and correction processing using a BCH code operation in which a 2-bit error is detected and corrected. An error check unit P2 is an example of a circuit that executes the error detection and correction processing using a BCH code operation. The error check unit P2 is formed by a combination of a RAM, a flip-flop, a lookup table, an arithmetic circuit such as a gate executing arithmetic operations, product-sum operations or the like, within, for example, an FPGA.

The error check unit P2 includes a BCH code generator P21, a RAM P22, and a BCH code checker P23. The BCH code generator P21 performs a BCH operation on input data, and encodes the data. The BCH code generator P21 includes a polynomial arithmetic unit P24, and a multiplexer (MUX in the drawing) P25. The BCH code checker P23 performs a BCH code operation on encoded data read from the RAM P22, and performs an error detection and an error correction. The BCH code checker P23 includes a polynomial arithmetic unit P26, a polynomial arithmetic unit P27, a bit error position specifying unit P28, and a bit error correction unit P29.

The error detection and correction processing using the BCH code operation by the error check unit P2 is performed as, for example, following steps (1) to (8).

(1) A report value is input to the polynomial arithmetic unit P24. The polynomial arithmetic unit P24 performs a BCH code operation using a polynomial 1 on the report value. The polynomial 1 is determined in advance according to the code length of a BCH code. For example, in association with the BCH code operation with a code length of 15 bits and a report value of 7 bits, the polynomial arithmetic unit P24 performs an operation in which 8 bits of 0 are added to the end of the report value to make the report value as a bit string of 15 bits, a polynomial with the bit string as a coefficient is divided by the polynomial 1, and the remainder is set as an operation result. The polynomial 1 in FIG. 2 is a polynomial different from the polynomial 1 used in the error check unit P1 using the Hamming code in FIG. 1.

(2) The report value and a codeword are input to the multiplexer P25. The multiplexer P25 adds the codeword to the end of the report value to make a set, and the set is written on the RAM P22. In FIG. 2, a transmission word corresponds to a set of the report value and the codeword.

(3) It is assumed that a bit error has occurred by a soft error in the RAM P22. It is assumed that due to the bit error, a bit error of 2 bits or 1 bit has occurred in the set of the report value and the codeword.

(4) The set of the report value and the codeword is read from the RAM P22, and is input to the BCH code checker P23. In FIG. 2, a received word corresponds to the set of the report value and the codeword read from the RAM P22.

(5) The received word is input to each of the polynomial arithmetic units P26 and P27. The polynomial arithmetic unit P26 performs a BCH code operation using a polynomial 2 on the received word. The polynomial arithmetic unit P27 performs a BCH code operation using a polynomial 3 on the received word. The polynomial 2 and the polynomial 3 are polynomials having a relationship of polynomial 1=polynomial 2×polynomial 3 with respect to the polynomial 1 used in the polynomial arithmetic unit P24. Specifically, each of the polynomial arithmetic units P26 and P27 performs an operation in which a polynomial with the received word as a coefficient is divided by each of the polynomial 2 and the polynomial 3, and the remainder is set as each of syndromes S1 and S2.

(6) The syndromes S1 and S2 are input to the bit error position specifying unit P28. An error determination table that stores a correspondence between a combination of values of the syndromes S1 and S2 and a position of a bit error is stored in a lookup table. The bit error position specifying unit P28 specifies the position of the bit error of 1 bit or 2 bits in the received word based on the values of the input syndromes S1 and S2 and the error determination table. The specified position of the bit error in the received word is input to the bit error correction unit P29.

(7) The received word and the position of the bit error in the received word are input to the bit error correction unit P29. The bit error correction unit P29 inverts the bit at the position of the bit error in the received word, and corrects the bit error. (8) An error-corrected bit string is output as a decoded word.

The correspondence between a combination of the syndromes S1 and S2 and the position of a bit error in the error determination table used in the error check unit P2 that performs detection and correction of a 2-bit error as illustrated in FIG. 2 is determined in advance by an algorithm of the BCH code.

The combinations of the syndromes S1 and S2 may include a combination indicating a 1-bit error and a position of a bit error, a combination indicating a 2-bit error and a position of a bit error, a combination indicating an error absence, and a combination indicating not applicable (n/a). For example, when a 3-bit error has occurred, the combination of the syndromes S1 and S2 indicates either not applicable or a 2-bit error. Thus, when the combination of the syndromes S1 and S2 indicates a 2-bit error, it is difficult to distinguish whether a 2-bit error has occurred, or a 3-bit error has occurred. That is, when the combination of the syndromes S1 and S2 indicates a 2-bit error, there is a possibility that even though a 3-bit error has occurred, the 3-bit error may be erroneously determined as a 2-bit error. In this case, when the combination of the syndromes S1 and S2 indicates a 2-bit error, there is a possibility that even though a 3-bit error has actually occurred, an erroneous 2-bit error correction is carried out, thereby affecting a circuit or device at a subsequent stage.

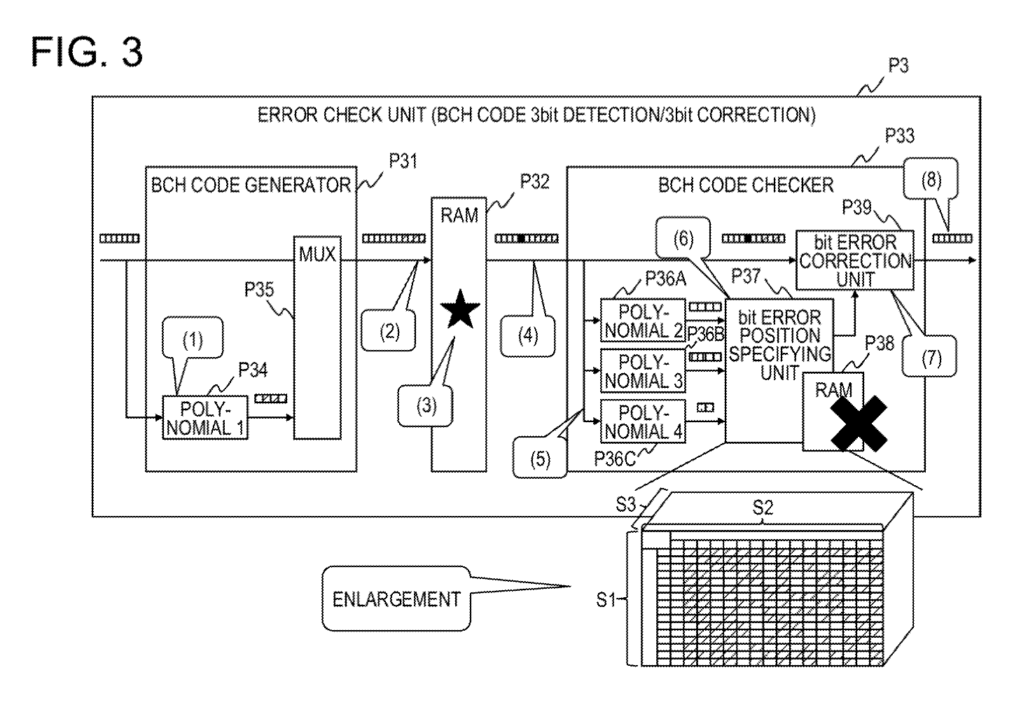

FIG. 3 is a view illustrating an example of an error detection and correction processing using a BCH code operation, in which a 3-bit error is detected and corrected. An error check unit P3 is an example of a circuit that executes the error detection and correction processing using a BCH code operation. The error check unit P3 is formed by a combination of a RAM, a flip-flop, a lookup table, an arithmetic circuit such as a gate executing arithmetic operations, product-sum operations or the like, within, for example, an FPGA.

The error check unit P3 includes a BCH code generator P31, a RAM P32, and a BCH code checker P33. The BCH code generator P31 includes a polynomial arithmetic unit P34, and a multiplexer (MUX in the drawing) P35. The BCH code checker P33 includes a polynomial arithmetic unit P36A, a polynomial arithmetic unit P36B, a polynomial arithmetic unit P36C, a bit error position specifying unit P37, and a bit error correction unit P39.

In steps (1) to (4) of the error detection and correction processing using the BCH code operation by the error check unit P3, a transmission word is written in the RAM P32, and a received word is read therefrom in substantially the same manner as, for example, steps (1) to (4) of the error detection and correction processing using the BCH code operation by the error check unit P2 in FIG. 2.

In step (5) of the error detection and correction processing using the BCH code operation by the error check unit P3, the BCH code operation is performed on the received word, using each of polynomials 2, 3, and 4. The polynomials 2, 3, and 4 are polynomials having a relationship of polynomial 1=polynomial 2×polynomial 3×polynomial 4 with respect to the polynomial 1 used in the polynomial arithmetic unit P34. Syndromes S1, S2, and S3 are acquired by the polynomial arithmetic units P36A, P36B, and P36C.

(6) The syndromes S1, S2, and S3 are input to the bit error position specifying unit P37. An error determination table held by the bit error position specifying unit P37 is prepared for the combinations of the syndromes S1, S2, and S3, and thus, has a larger size than that of the error determination table of the error check unit P2 capable of detecting and correcting a 2-bit error as illustrated in FIG. 2.

For example, in the error check unit P2 using a 2-bit error detectable and correctable BCH code operation with a code length of 15 bits and a report value of 7 bits, the error determination table includes 256 combinations (=16 (syndrome S1)×16 (syndrome S2)). Meanwhile, in the error check unit P3 using a 3-bit error detectable and correctable BCH code operation with a code length of 15 bits and a report value of 5 bits, the error determination table includes 1,204 combinations (=16 (syndrome S1)×16 (syndrome S2)×4 (syndrome S3)).

In the error check unit P3 using the 3-bit error detectable and correctable BCH code operation, the size of the error determination table increases. However, when it is assumed that the RAM is applied to a table processing that derives a value of a corresponding field using a syndrome as a key, there is a possibility that the RAM may further induce a bit error. Meanwhile, when it is assumed that the error determination table is logically configured using the flip-flop or the lookup table, a circuit scale is enlarged in the error detection and correction processing using the 3-bit error detectable and correctable BCH code operation.

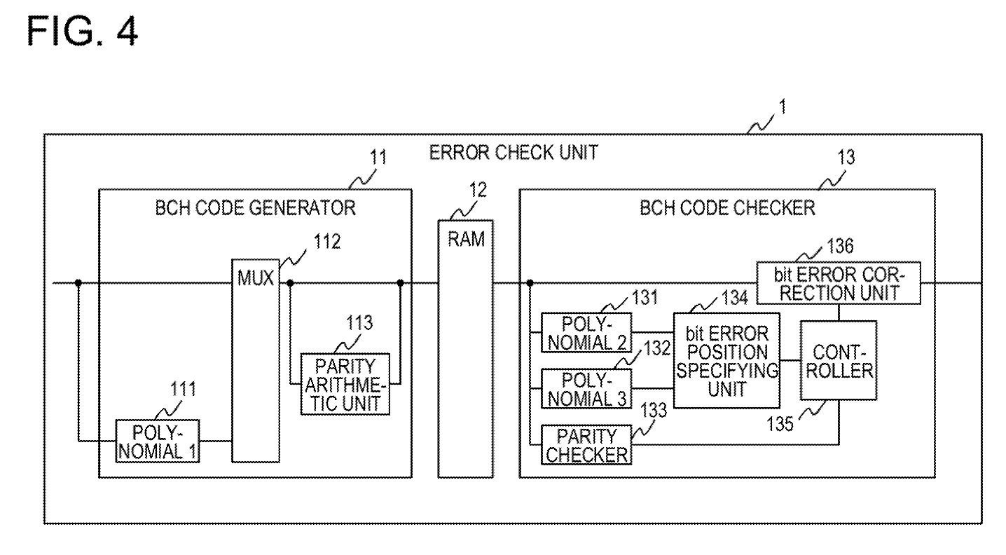

FIG. 4 is an example of an error check unit that executes an error detection and correction processing according to the first embodiment. An error check unit 1 is formed by a combination of elements such as a RAM, a flip-flop, a lookup table, and a arithmetic circuit such as a gate executing four arithmetic operations, product-sum operations or the like, within, for example, an FPGA. The error check unit 1 or the FPGA mounted with the error check unit 1 corresponds to an example of a “data processing system,” or a “data processing apparatus.”

The error check unit 1 includes a BCH code generator 11, a RAM 12, and a BCH code checker 13. The BCH code generator 11 performs a BCH code operation on a report value, and performs BCH encoding on the value. The BCH code generator 11 includes a polynomial arithmetic unit 111, a multiplexer (MUX in the drawing) 112, and a parity arithmetic unit 113. The BCH code checker 13 performs a BCH code operation on the report value encoded by the BCH code generator 11, and performs an error detection and an error correction. The BCH code checker 13 includes a polynomial arithmetic unit 131, a polynomial arithmetic unit 132, a parity checker 133, a bit error position specifying unit 134, a controller 135, and a bit error correction unit 136.

The error check unit 1 according to the first embodiment has a configuration in which the parity arithmetic unit 113, the parity checker 133, and the controller 135 are added to the configuration of the error check unit P2 (see, e.g., FIG. 2) using a BCH code operation in which a 2-bit error is detected and corrected. The error check unit 1 according to the first embodiment performs a parity check on a set of the report value and a codeword before the set is written on the RAM 12 and after the set is read from the RAM 12. The parity check is a processing of determining whether a parity bit of the set of the report value and the codeword before written on the RAM 12 is coincident with that read from the RAM 12.

The parity bit is a bit indicating whether the number of 1s included in a target bit string is an even number or an odd number. In the case of an even parity, the parity bit becomes “0” when the number of 1s included in the target bit string is an even number, and the parity bit becomes “1” when the number is an odd number. In the case of an odd parity, the parity bit becomes “0” when the number of 1s included in the target bit string is an odd number, and the parity bit becomes “1” when the number is an even number. In the first embodiment, either an even parity or an odd parity may be used. In the case of the even parity, the parity bit is obtained as an exclusive OR (XOR) of all bits in the target bit string. In the case of the odd parity, the parity bit is obtained as an exclusive not OR (XNOR) of all bits in the target bit string.

The case where a parity bit of the set of the report value and the codeword before written on the RAM 12 is coincident with that read from the RAM 12 indicates that no bit error has occurred, or an even number of bit errors have occurred. The case where a parity bit of the set of the report value and the codeword before written on the RAM 12 is not coincident with that read from the RAM 12 indicates that an odd number of bit errors have occurred.

That is, the error check unit 1 according to the first embodiment may verify whether an error is a 2-bit error or a 3-bit error on the basis of the determination result of the 2-bit error based on the error determination table by performing the parity check. This may improve the accuracy of detection of a 2-bit error and a 3-bit error. That is, the error check unit 1 according to the first embodiment may detect a bit error of up to 3 bits, and may correct a bit error of up to 2 bits.

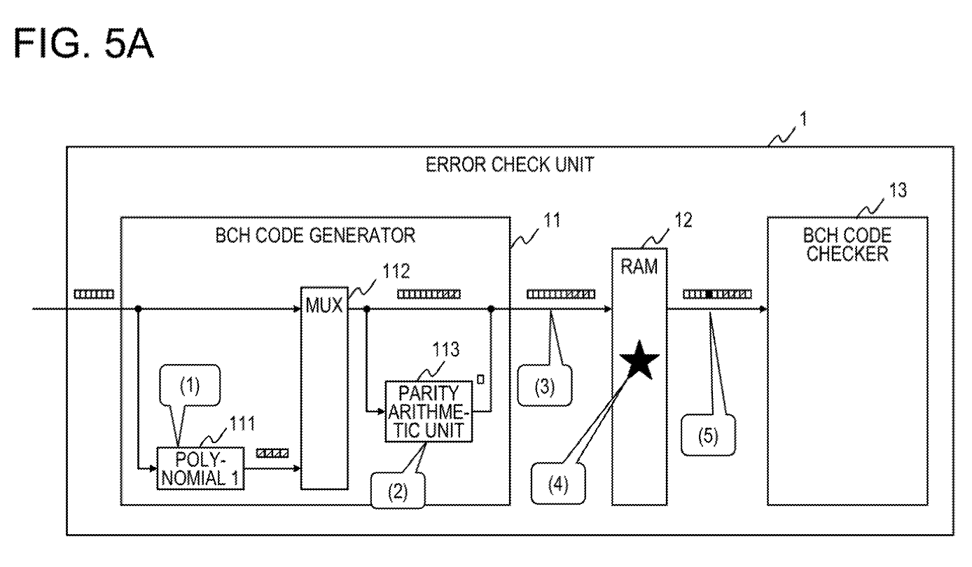

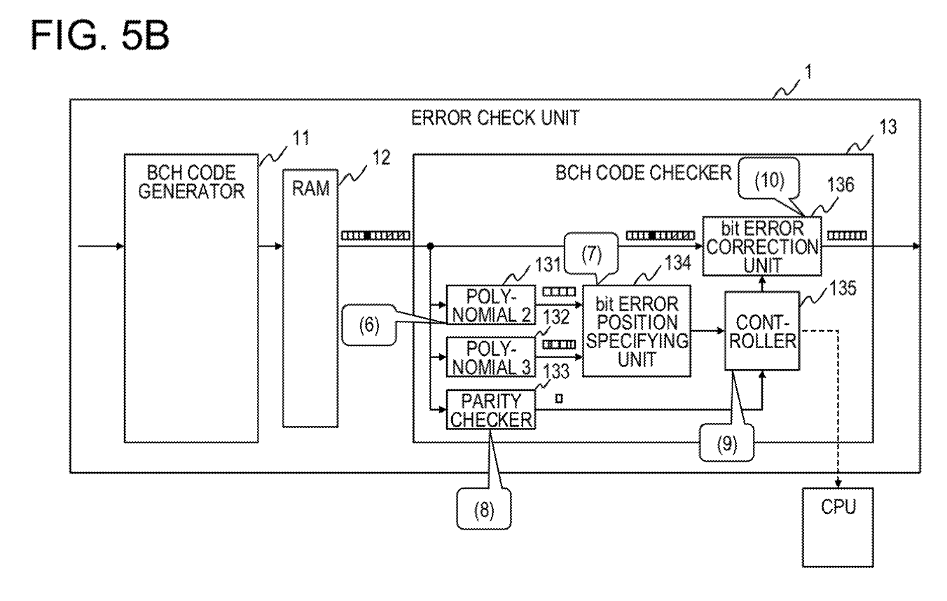

FIGS. 5A and 5B are views illustrating an example of a flow of a processing of the error check unit 1 according to the first embodiment. The processing is performed as following steps (1) to (10). (1) A report value is input to the polynomial arithmetic unit 111. The polynomial arithmetic unit 111 performs a BCH code operation using a polynomial 1 on the report value, and outputs a codeword as an operation result. Specific calculation contents are the same as those in the polynomial arithmetic unit P24 in FIG. 2.

(2) The report value and the codeword are input to the multiplexer 112. The multiplexer 112 adds the codeword at the end of the report value and outputs the codeword and the report value. The polynomial arithmetic unit 111 or the polynomial arithmetic unit 111 and the multiplexer 112 correspond to an example of a “first arithmetic circuit.” The processing performed in the polynomial arithmetic unit 111 or the polynomial arithmetic unit 111 and the multiplexer 112 is an example of a “first error correction code operation.” A set of the report value and the codeword output from the multiplexer 112 is an example of a “first bit string.”

(3) The set of the report value and the codeword output from the multiplexer 112 is input to the parity arithmetic unit 113. The parity arithmetic unit 113 obtains a parity bit of the set of the report value and the codeword. The parity bit on the set of the report value and the codeword is output from the parity arithmetic unit 113. The BCH code generator 11 has a circuit configuration in which the parity bit output from the parity arithmetic unit 113 is added to the head of the set of the report value and the codeword. The parity bit and the set of the report value and the codeword are written on the RAM 12. In the first embodiment, a transmission word output from the BCH code generator 11 is the set of the parity bit, the report value, and the codeword. The parity arithmetic unit 113 is an example of a “parity arithmetic circuit.”

(4) There is a possibility that a bit error may occur due to a soft error in the RAM 12. The bit error causes a change in values of the set of the parity bit, the report value, and the codeword written on the RAM 12.

(5) The set of the parity bit, the report value, and the codeword read from the RAM 12 is input to the BCH code checker 13. In the first embodiment, a received word corresponds to the set of the parity bit, the report value, and the codeword read from the RAM 12.

Thereafter, in step (6) of FIG. 5B, the received word is input to each of the polynomial arithmetic unit 131 and the polynomial arithmetic unit 132. The polynomial arithmetic unit 131 performs a BCH code operation using a polynomial 2 on the bit string corresponding to the report value and the codeword in the received word. The polynomial arithmetic unit 132 performs a BCH code operation using a polynomial 3 on the bit string corresponding to the report value and the codeword in the received word. The polynomials 2 and 3 are polynomials having a relationship of polynomial 1=polynomial 2×polynomial 3 with respect to the polynomial 1 used in the polynomial arithmetic unit 111. Specifically, each of the polynomial arithmetic units 131 and 132 performs an operation in which a polynomial with the received word as a coefficient is divided by each of the polynomial 2, and the polynomial 3, and the remainder is set as each of syndromes S1 and S2. Each of the polynomial arithmetic units 131 and 132 corresponds to an example of a “second arithmetic circuit.” An operation using the polynomials 2 and 3 performed in the polynomial arithmetic units 131 and 132 is an example of a “second error correction code operation.” Each of the syndromes S1 and S2 is an example of an “operation result of a second error correction code operation.”

(7) The syndromes S1 and S2 are input to the bit error position specifying unit 134. The bit error position specifying unit 134 stores an error determination table in a lookup table. The bit error position specifying unit 134 inputs values of the input syndromes S1 and S2 as keys into the error determination table, and acquires a value of a field of the error determination table corresponding to the syndromes S1 and S2, as a determination result. The determination result by the error determination table indicates any one of error absence, a 1-bit error and its error position, a 2-bit error and its error position, and not applicable (described below). The determination result by the error determination table is output to the controller 135. The bit error position specifying unit 134 is an example of a “specifying circuit.”

(8) The received word is also input to the parity checker 133. The parity checker 133 performs a parity check on the received word. Specifically, in the parity checker 133, an operation of obtaining a parity bit of the received word is performed. In the parity check, it may be determined whether the parity bit included in the received word is coincident with the parity bit in the set of the report value and the codeword included in the received word. Thus, in the parity check, an exclusive OR or a negative exclusive OR of the parity bit included in the received word, and the parity bit in the set of the report value and the codeword included in the received word may be obtained. The parity bit is an exclusive OR or a negative exclusive OR of all bits included in the target bit string. Accordingly, in the parity check of the parity checker 133, the parity bit of all bits included in the received word may be obtained.

In the even parity, the case where a parity bit of the received word is “0” indicates that there is no parity error. The case where a parity bit of the received word is “1” indicates that there is a parity error. In the odd parity, the case where a parity bit of the received word is “1” indicates that there is no parity error. The case where a parity bit of the received word is “0” indicates that there is a parity error. The parity check result obtained by the parity checker 133 (in actuality, the parity bit of the received word) is output to the controller 135. The parity checker 133 is an example of a “parity check circuit.”

(9) The determination result by the error determination table from the bit error position specifying unit 134 and the parity check result from the parity checker 133 are input to the controller 135. When the determination result by the error determination table indicates an error absence, or a 1-bit error and its error position, the controller 135 outputs the determination result by the error determination table to the bit error correction unit 136. When the determination result by the error determination table indicates not applicable, the controller 135 detects an error of 3 or more bits, and notifies a central processing unit (CPU) of a device mounted with the error check unit 1 of a 3-bit error. In the first embodiment, the error of 3 or more bits is handled equivalently with a 3-bit error. Thus, when the error of 3 or more bits is detected, the CPU is notified of the 3-bit error.

When the determination result by the error determination table indicates a 2-bit error and its error position, the controller 135 verifies whether an error is a 2-bit error or a 3-bit error using the parity check result. When the parity check result indicates that there is no parity error, the controller 135 confirms the 2-bit error as the determination result by the error determination table, and outputs the determination result by the error determination table to the bit error correction unit 136. When the parity check result indicates that there is a parity error, the controller 135 detects the 3-bit error and notifies the CPU of a device mounted with the error check unit 1 of the 3-bit error. The controller 135 is an example of a “control circuit.”

(10) The received word and the determination result by the error determination table are input to the bit error correction unit 136. When the determination result by the error determination table indicates a 1-bit error or a 2-bit error, the bit error correction unit 136 inverts the bit at the position of the bit error in the received word, thereby correcting the bit error. Thereafter, the bit error correction unit 136 outputs an error-corrected bit string corresponding to the report value in the received word, as a decoded word. When an error of 3 or more bits is detected, the bit error correction unit 136 does not correct the bit error, and outputs the bit string corresponding to the report value in the received word, as a decoded word.

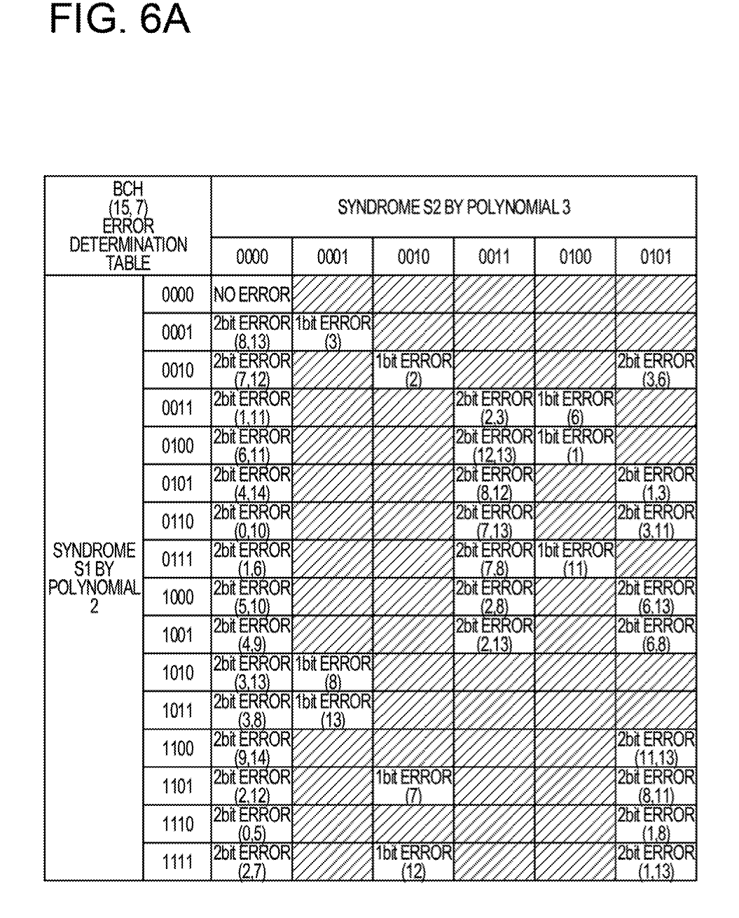

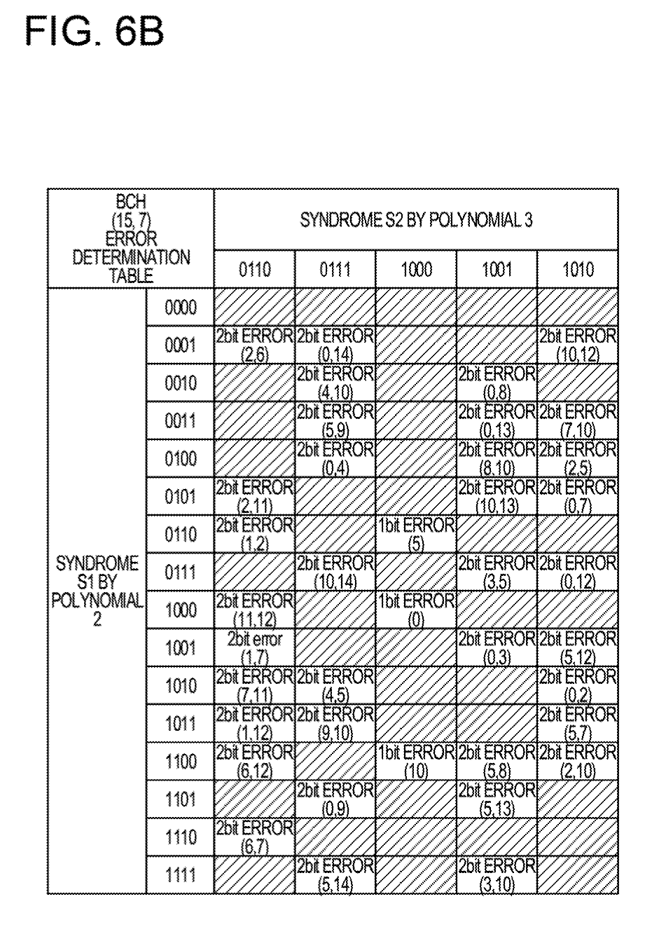

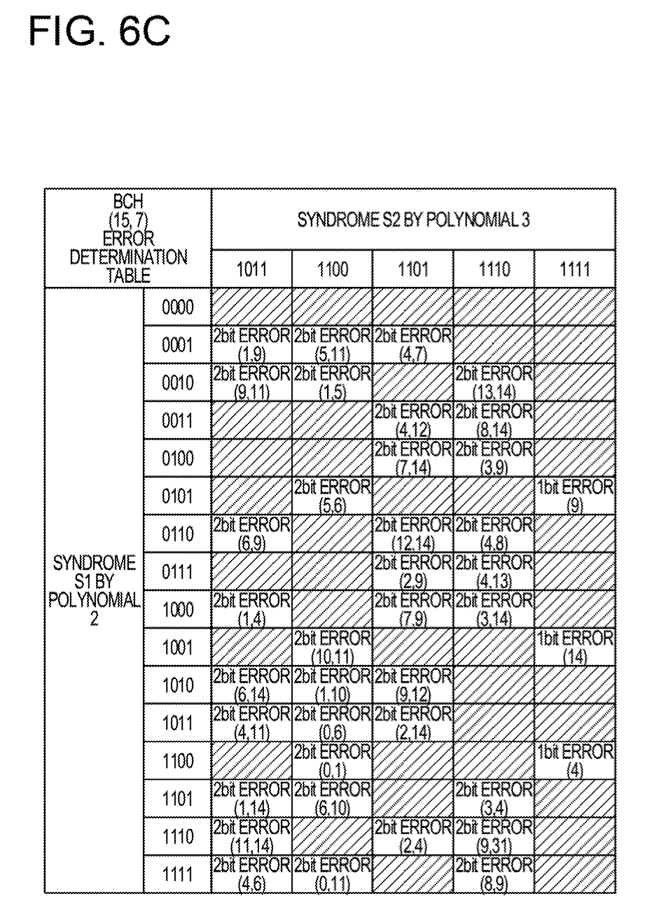

FIGS. 6A to 6C are an example of the error determination table. The error determination table illustrated in FIGS. 6A to 6C is an error determination table of a BCH code operation with a report value of 7 bits and a code length of 15 bits. The values of combinations of the syndromes S1 and S2 in the error determination table are known in advance by the algorithm of the BCH code operation.

For example, a value of the field of the error determination table corresponding to a combination of a syndrome S1 (0000) and a syndrome S2 (0000) is “error absence.” For example, the value of the field of the error determination table corresponding to a combination of a syndrome S1 (1000) and a syndrome S2 (0011) is 2-bit error (2, 8). The value of the field of the error determination table, 2-bit error (2, 8), indicates that the set of the report value and the codeword read from the RAM 12 includes a 2-bit error, and a position of the bit error is a position of D2 and D8. The position of the bit error, D(x−1), indicates an x-th position from the least significant bit. That is, the position of the bit error, D2, indicates that there is an error in the 3^{rd} bit from the least significant bit. When the value of the field of the error determination table corresponding to a combination of the syndromes S1 and S2 is blank, the value is not applicable and the value is returned. The error determination table is an example of a “correspondence between an operation result of a second error correction code operation, the number of at most N bit error, and an error position.”

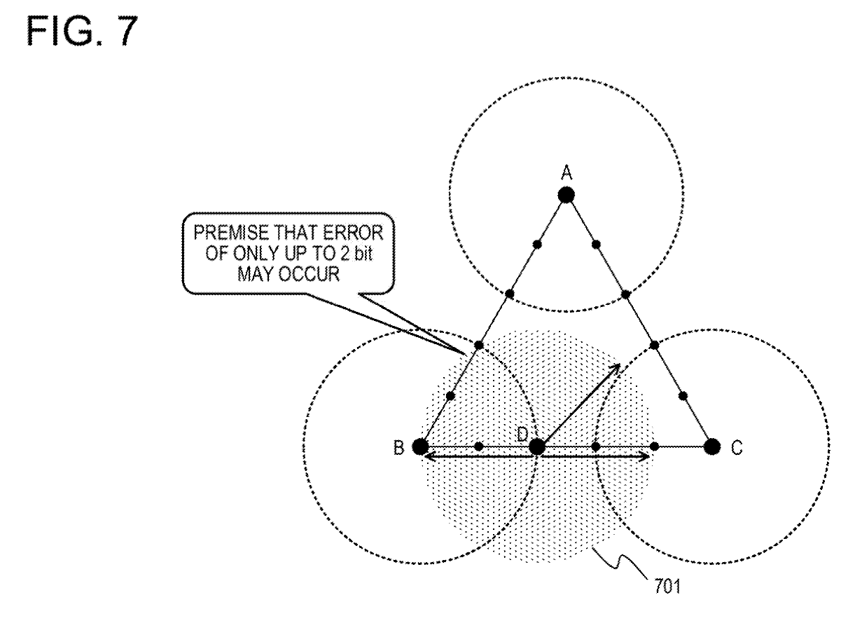

Descriptions will be made on that it is possible to specify a 2-bit error or a 3-bit error by the error check unit 1 according to the first embodiment when a determination result of the error determination table indicates a 2-bit error, with reference to FIGS. 7, 8, and 9.

FIGS. 7, 8, and 9 illustrate inter-code distances of three values each of which does not become other two values even when any two bits are inverted. For example, A is 11000111, B is 00000000, and C is 11111000. Each of these does not become other two values or another value in which any two bits are inverted even when any two bits are inverted. Thus, the codes of A, B, and C are distant from each other by at least 5.

In FIGS. 7, 8, and 9, a circle centered on each of A, B, and C, and indicated by a dotted line indicates an error correctable range by a 2-bit error detectable and correctable BCH code operation. Hereinafter, it is assumed that A, B, and C are values in which a bit error has not yet occurred. It is assumed that D illustrated in FIGS. 7, 8, and 9 is a value in which a bit error has occurred. D is, for example, 11000000. D is a value obtained by inverting first two bits of B, and is distant from B by 2. D is a value obtained by inverting three bits of C, and is distant from C by 3.

FIG. 7 is a view illustrating a relationship between A, B, C, and D in an error detection and correction using a 2-bit error detectable and correctable BCH code operation, on the premise that an error of 2 bits at maximum occurs. A circle 701 centered on D in FIG. 7 indicates a range in which D may take values as a value in which a bit error has not yet occurred. FIG. 7 is based on the premise that an error of 2 bits at maximum occurs, and thus the circle 701 is a circle centered on D and having a radius of two gradations. B is present in the circle 701 within two gradations of D, and thus it is specified that an original value of D is B. D is present within a circle centered on B, and thus an error correction may be performed.

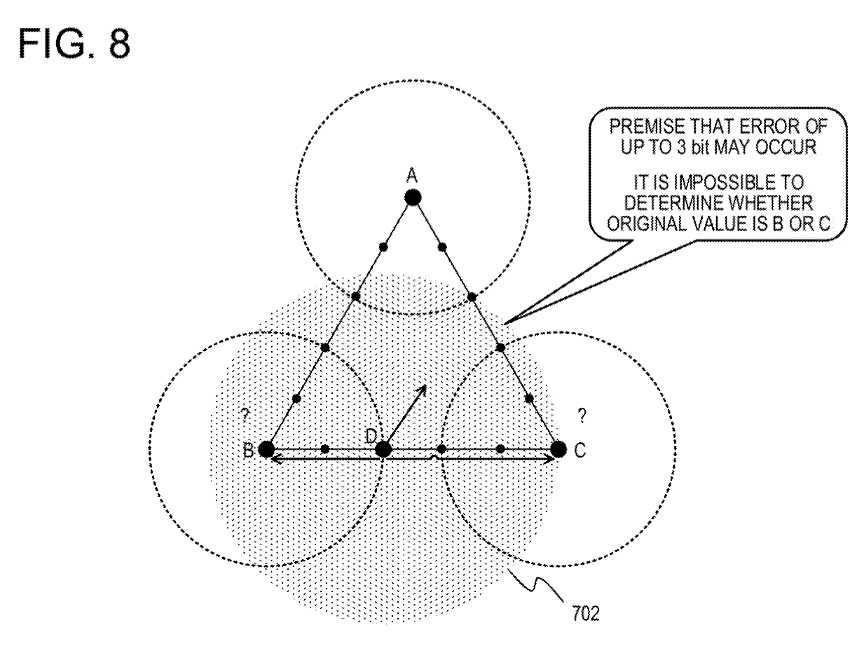

FIG. 8 is a view illustrating a relationship between A, B, C, and D in an error detection and correction using a 2-bit error detectable and correctable BCH code operation, on the premise that an error of 3 bits at maximum occurs. A circle 702 centered on D in FIG. 8 indicates a range in which D may take values as a value in which a bit error has not yet occurred. In FIG. 8, it is assumed that an error of 3 bits at maximum occurs, and thus the circle 702 is a circle centered on D and having a radius of three gradations. In FIG. 8, B and C are present within the circle 702 centered on D. Thus, even when a 2-bit error is detected using the 2-bit error detectable and correctable BCH code operation, it is not possible to specify whether the original value of D is B or C.

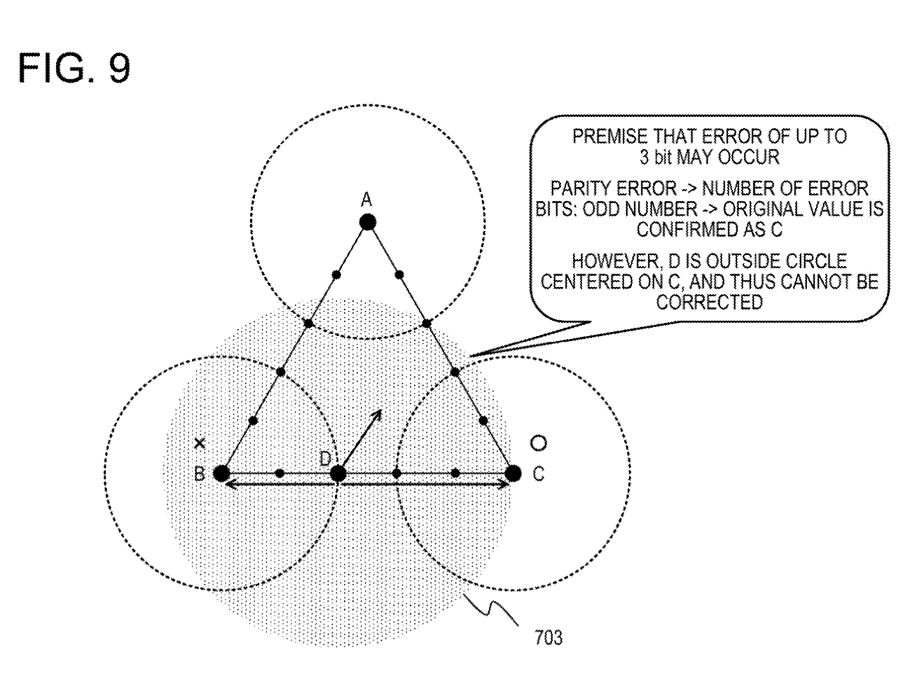

FIG. 9 is a view illustrating a relationship between A, B, C, and D in an error detection and correction by the error check unit 1 according to the first embodiment, on the premise that an error of 3 bits at maximum occurs. A circle 703 centered on D in FIG. 9 indicates a range in which D may take values as a value in which a bit error has not yet occurred. FIG. 9 is based on the premise that an error of 3 bits at maximum occurs, and thus the circle 703 is a circle centered on D and having a radius of three gradations. In FIG. 9, B and C are present within the circle 703 centered on D.

In the error check unit 1 according to the first embodiment, a parity check is performed by the parity checker 133. When there is a parity error, it is specified that the number of bit error is an odd number. When there is no parity error, it is specified that the number of bit error is an even number.

Accordingly, in the state illustrated in FIG. 9, in the case where a parity error is detected, since the number of bit error is an odd number, it is specified that the original value of D is C not B. However, since D is not present in the circle centered on C, it is not possible to correct the error. Thus, the error check unit 1 according to the first embodiment may detect a bit error of up to 3 bits, but may correct only a bit error of up to 2 bits, except for a 3-bit error.

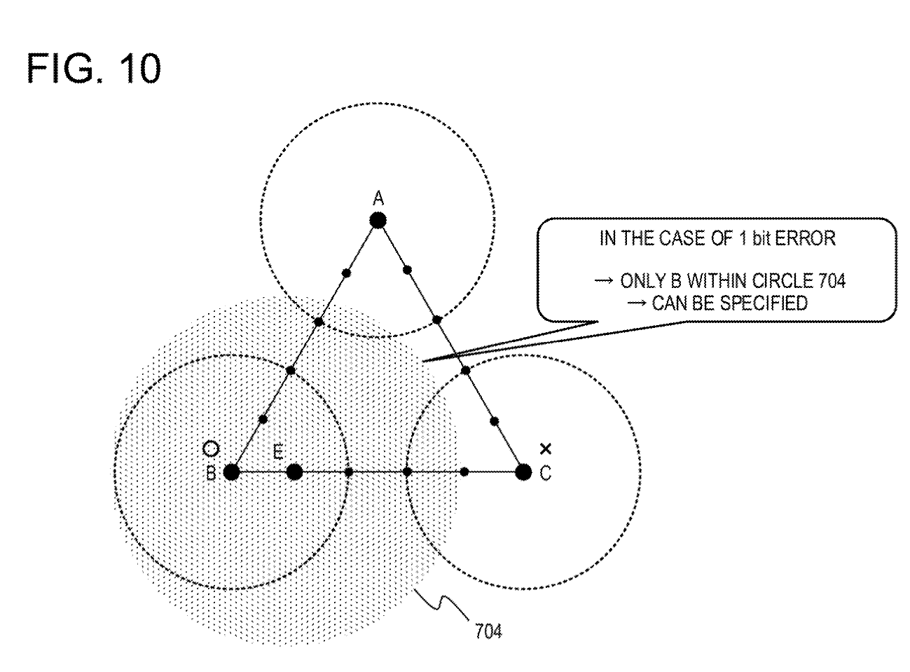

FIG. 10 is a view illustrating a relationship between A, B, C, and E in an error detection and correction by the error check unit 1 according to the first embodiment, on the premise that an error of 3 bits at maximum occurs. E is a value occurring by a 1-bit error. E is, for example, 10000000 and is a value obtained by inverting first one bit of B.

In FIG. 10, a circle 704 indicates a range in which E may take values as a value in which a bit error has not yet occurred. FIG. 10 is based on the premise that an error of 3 bits at maximum occurs, and thus the circle 704 is a circle centered on E and having a radius of three gradations. In FIG. 10, B is present within the circle 704 centered on E, and A and C are present outside the circle 704. Thus, it is possible to specify that an original value of E is B. Since E is present within the circle centered on B, an error correction may be performed.

Accordingly, in the error correction by the error check unit 1 according to the first embodiment, when a 1-bit error occurs, the error may be detected and corrected using an error determination table of a BCH code operation.

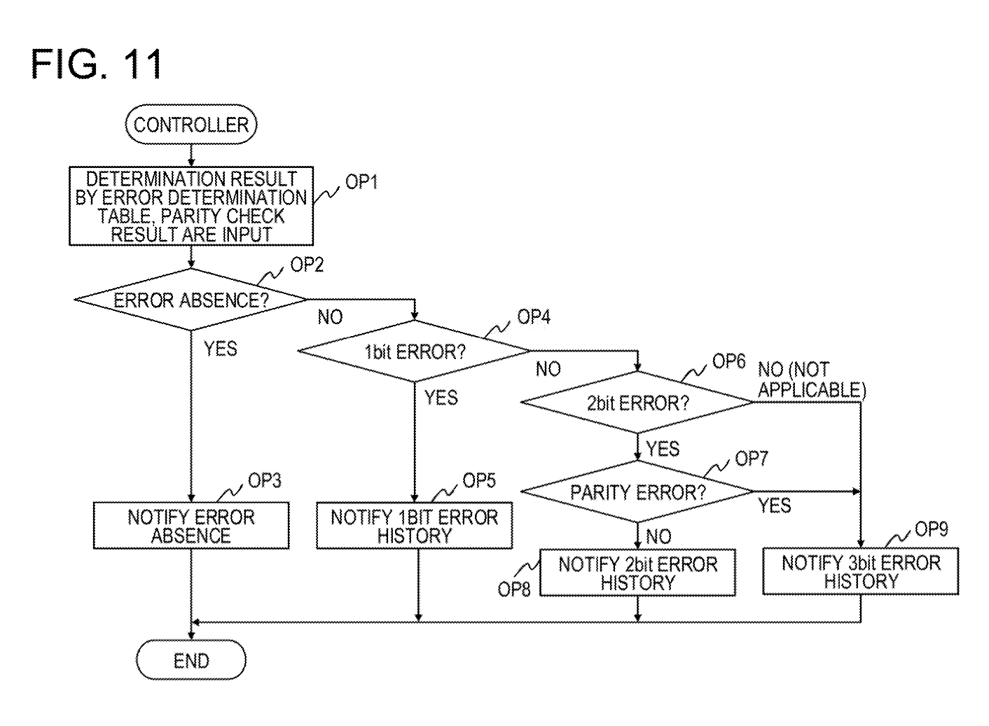

FIG. 11 is an example of a flow chart of a process of the controller 135 of the error check unit 1 according to the first embodiment. The flow chart of the process of the controller 135 of the error check unit 1 as illustrated in FIG. 11 is implemented by a combination of a D-type flip flop and a lookup table in an FPGA.

In OP1, the determination result by the error determination table from the bit error position specifying unit 134 and the parity check result from the parity checker 133 are input to the controller 135.

In OP2, the controller 135 determines whether the determination result by the error determination table indicates error absence. When it is determined that the determination result by the error determination table indicates error absence (OP2: “YES”), the process proceeds to OP3. When it is determined that the determination result by the error determination table does not indicate error absence (OP2: “NO”), the process proceeds to OP4.

In OP3, the controller 135 notifies the bit error correction unit 136 of error absence. Then, the process illustrated in FIG. 11 ends.

In OP4, the controller 135 determines whether the determination result by the error determination table indicates 1-bit error detection. When it is determined that the determination result by the error determination table indicates 1-bit error detection (OP4: “YES”), the process proceeds to OP5. When it is determined that the determination result by the error determination table does not indicate 1-bit error detection (OP4: “NO”), the process proceeds to OP6.

In OP5, the controller 135 outputs a determination result by the error determination table, which indicates a 1-bit error and a bit error position, to the bit error correction unit 136 and the CPU of a device mounted with the error check unit 1. Then, the process illustrated in FIG. 11 ends.

In OP6, the controller 135 determines whether the determination result by the error determination table indicates 2-bit error detection. When it is determined that the determination result by the error determination table indicates 2-bit error detection (OP6: “YES”), the process proceeds to OP7. When it is determined that the determination result by the error determination table does not indicate 2-bit error detection, that is, not applicable (OP6: “NO”), the process proceeds to OP9.

In OP7, the controller 135 determines whether the parity check result indicates that there is an error. To the controller 135, a parity bit of a received word is input as a parity check result from the parity checker 133. For example, in an even parity, the case where the parity bit of the received word is “1” indicates that there is a parity error. For example, in an even parity, the case where the parity bit of the received word is “0” indicates that there is no parity error.

When it is determined that the parity check result indicates that there is an error (OP7: “YES”), the process proceeds to OP9. When it is determined that the parity check result indicates that there is no error (OP7: “NO”), the process proceeds to OP8.

In OP8, since the parity check result indicates an error absence, the detection result of the 2-bit error is confirmed, and the controller 135 outputs a determination result by the error determination table, which indicates a 2-bit error and a bit error position, to the bit error correction unit 136 and the CPU of a device mounted with the error check unit 1. Then, the process illustrated in FIG. 11 ends.

In OP9, a 3-bit error is detected, and the controller 135 outputs the 3-bit error to the bit error correction unit 136 and the CPU of a device mounted with the error check unit 1. Then, the process illustrated in FIG. 11 ends.

In the case of a 1-bit error or a 2-bit error, an error position is specified and an error correction is performed by the bit error correction unit 136. In the case of a 3-bit error, since an error position is not specified, an error correction is not performed, but a decoded word including a bit error is output. However, since the 3-bit error is notified to the CPU of the device mounted with the error check unit 1, data lost due to a soft error in the RAM 12 may be compensated by a retransmission processing by the CPU. When the 3-bit error occurs, the CPU may rewrite the RAM 12 to an initial state, so as to repair the soft error.

### Specific Example

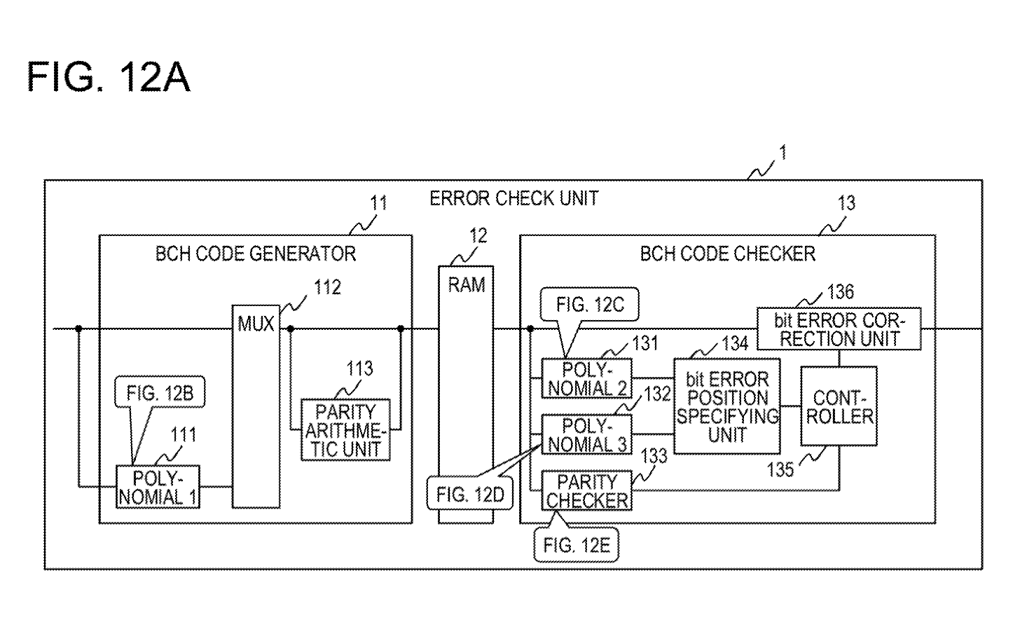

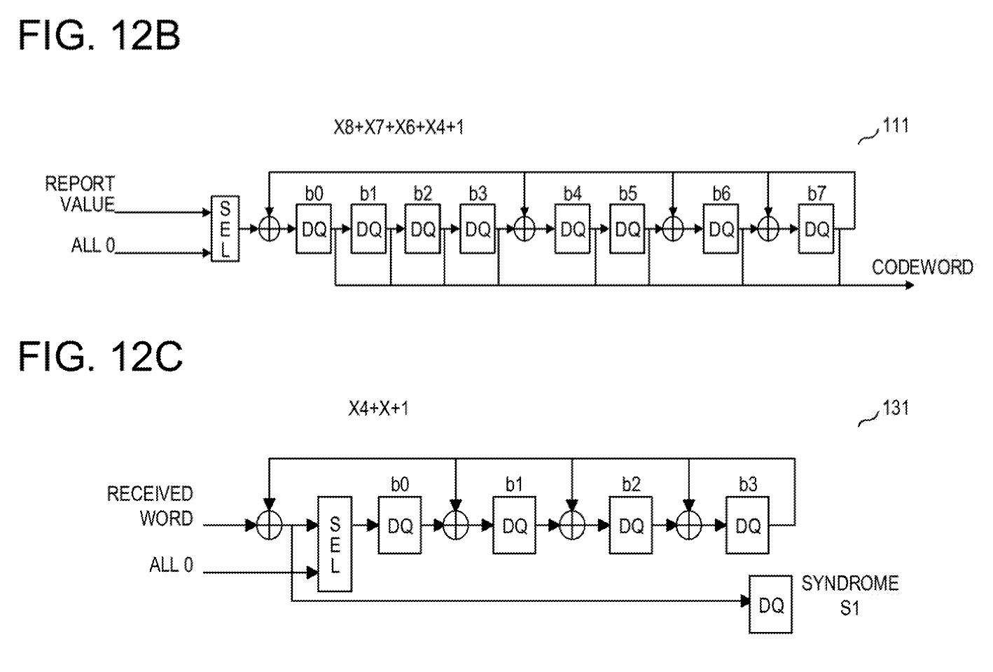

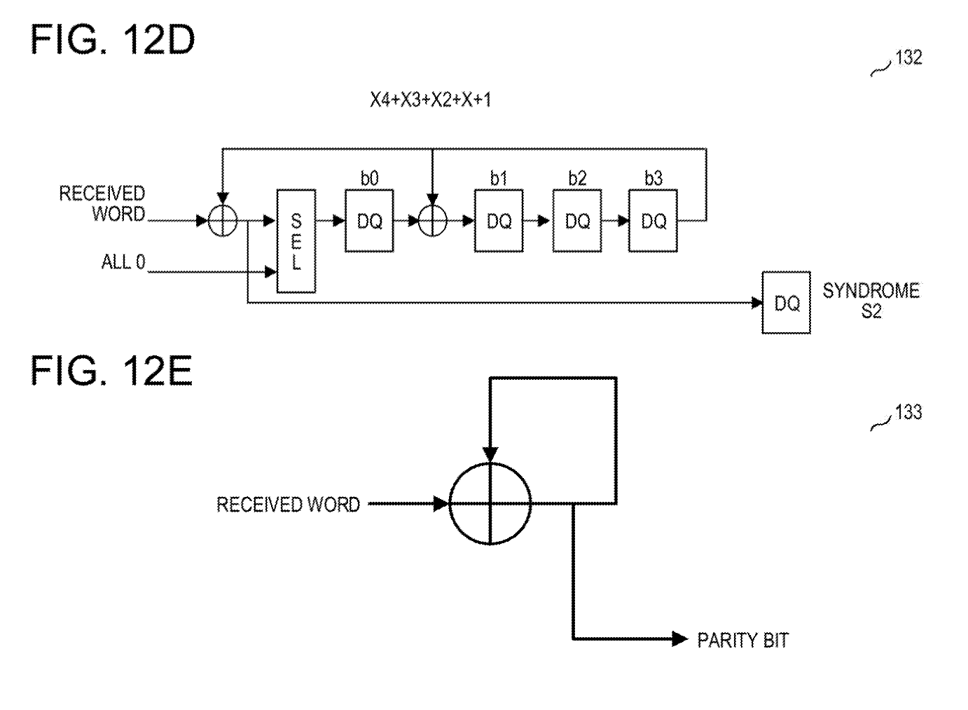

FIGS. 12A to 12E are views illustrating an exemplary circuit configuration of a polynomial and a polynomial arithmetic unit in a specific example. In the specific example, the polynomial 1 used in the polynomial arithmetic unit 111 is X8+X7+X6+X4+1. The polynomial 2 used in the polynomial arithmetic unit 131 is X4+X+1. The polynomial 3 used in the polynomial arithmetic unit 132 is X4+X3+X2+X+1. The circuit configuration of each of the polynomials 1 to 3 is as illustrated in FIGS. 12A to 12E, for example, using a D-type flip-flop. In the specific example, it is assumed that the parity arithmetic unit 113 and the parity checker 133 obtain an even parity of all bits of a received word. Thus, since the parity arithmetic unit 113 and the parity checker 133 obtain an exclusive OR of all bits of the received word, the circuit configuration becomes an exclusive OR circuit.

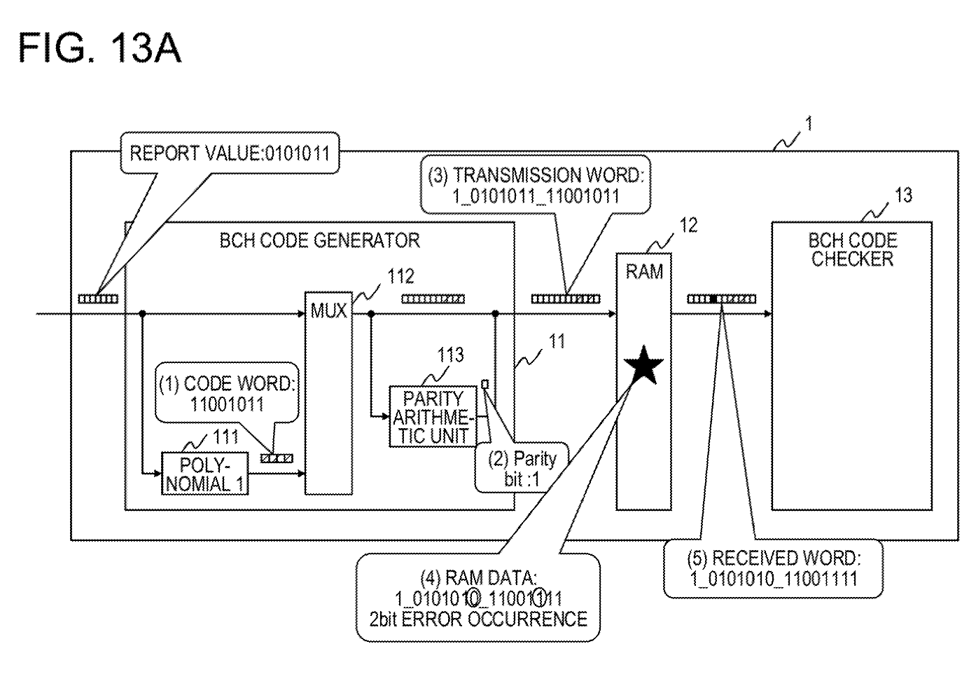

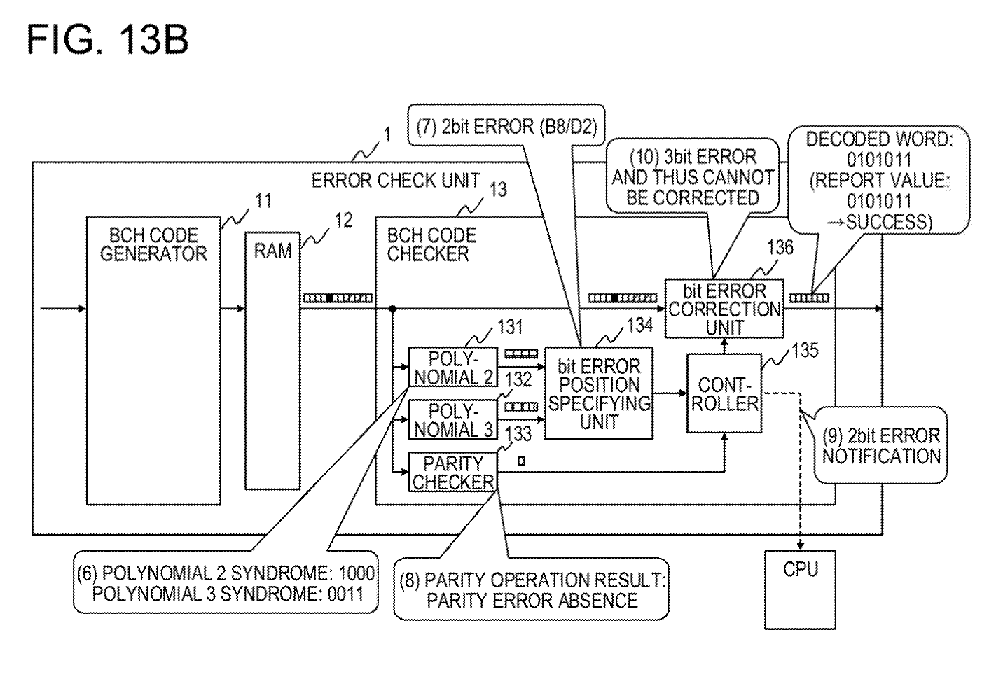

FIGS. 13A and 13B are views illustrating an example of a processing when a 2-bit soft error occurs in the RAM 12 of the error check unit 1 according to the specific example. A report value in FIG. 13A is assumed to be 0101011.

(1) The report value 0101011 is input to the polynomial arithmetic unit 111, and a codeword 11001011 is generated using the polynomial 1 (X8+X7+X6+X4+1).

(2) A set of the report value and the codeword, 0101011_11001011, is input to the parity arithmetic unit 113, and an even parity bit, 1, is obtained.

(3) The parity bit, the report value, and the codeword are output as a transmission word 1_0101011_11001011 from the BCH code generator 11, and written on the RAM 12.

(4) It is assumed that a bit error due to a soft error occurs in the parity bit, the report value, and the codeword stored in the RAM 12. The bit error occurring at this time is a 2-bit error, and it is assumed that bits at third and ninth positions (D2, D8) from the least significant bit are inverted.

(5) The parity bit, the report value, and the codeword read from the RAM 12 are input as a received word to the BCH code checker 13. The received word is 1_0101010_11001111.

(6) As illustrated in FIG. 13B, the received word is input to the polynomial arithmetic units 131 and 132, and a syndrome S1:1000, and a syndrome S2:0011 are generated using the polynomial 2 (X4+X+1), and the polynomial 3 (X4+X3+X2+X+1).

(7) The bit error position specifying unit 134 inputs the syndrome S1:1000 and the syndrome S2:0011 as keys to the error determination table (FIGS. 6A to 6C), and acquires a 2-bit error (D2, D8) as a value corresponding to the keys.

(8) The parity checker 133 performs a parity check on the received word. Since the even parity bit of the received word (1_0101010_11001111) is 0, the result of the parity check on the received word indicates “no parity error.”

(9) To the controller 135, the determination result by the error determination table: 2-bit error (D2, D8), and “no parity error” are input. Based on “no parity error,” the controller 135 confirms a 2-bit error (FIG. 11, OP6: YES, OP7: NO), and notifies the CPU of a device mounted with the error check unit 1 of the 2-bit error (FIG. 11, OP8).

(10) The bit error correction unit 136 corrects a bit error of the received word based on the determination result by the error determination table: 2-bit error (D2, D8). Specifically, bits at third and ninth positions (D2, D8) from the least significant bit of the received word 1_0101010_11001111 are inverted and corrected to 1_0101011_11001011.

A decoded word becomes an error-corrected bit string 0101011 corresponding to the report value of the received word. The decoded word has the same value as the report value 0101011. Therefore, as illustrated in FIGS. 13A and 13B, the error check unit 1 may detect and correct a 2-bit error.

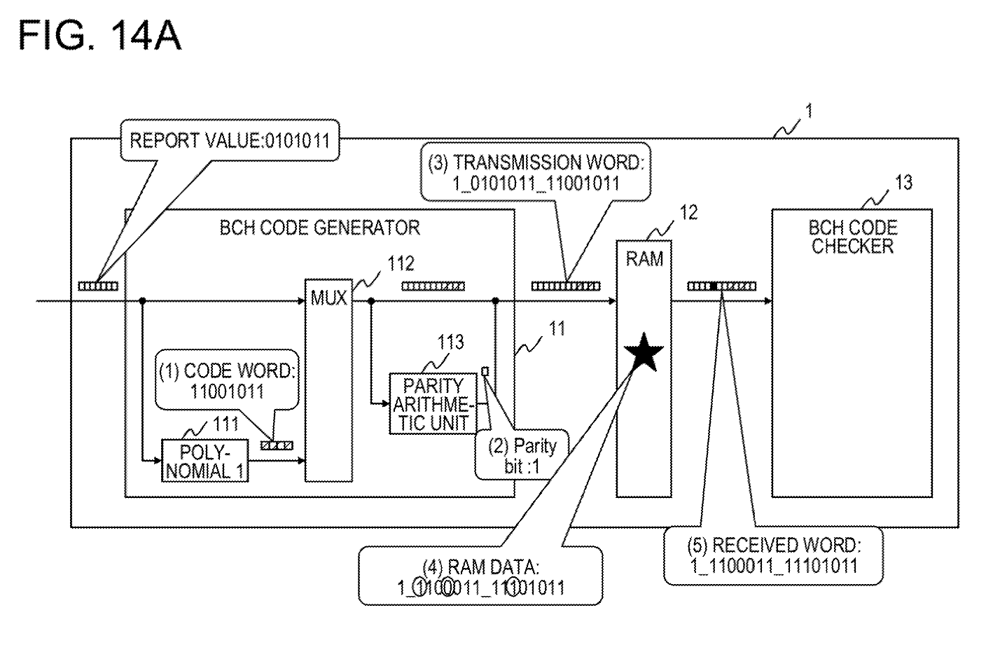

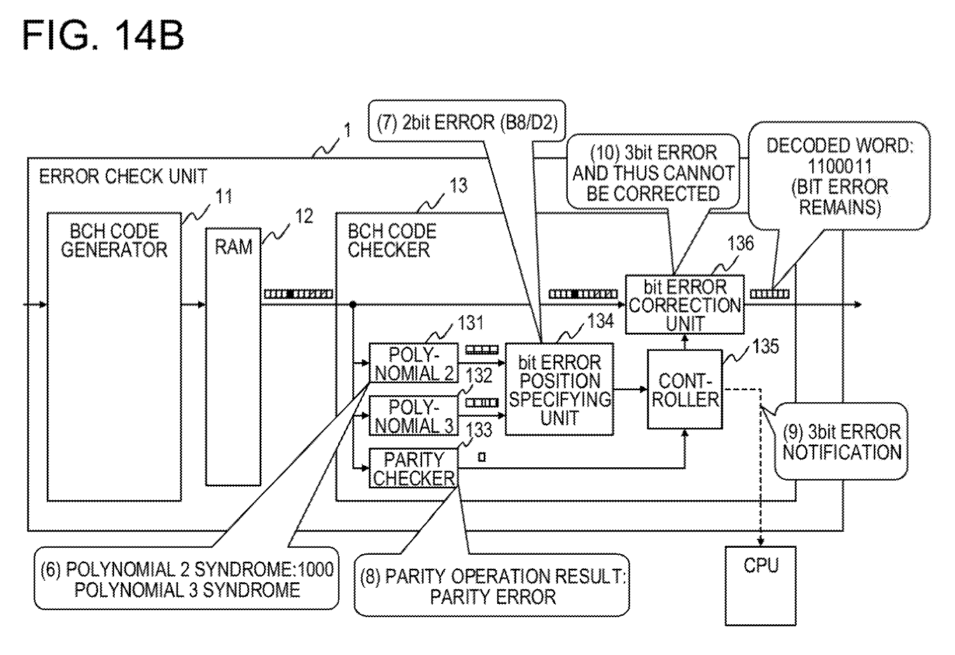

FIGS. 14A and 14B are views illustrating an example of a processing when a 3-bit soft error occurs in the RAM 12 of the error check unit 1 according to the specific example. A report value in FIG. 14A is assumed to be 0101011.

(1) The report value 0101011 is input to the polynomial arithmetic unit 111, and a codeword 11001011 is generated using the polynomial 1 (X8+X7+X6+X4+1).

(2) A set of the report value and the codeword, 0101011_11001011, is input to the parity arithmetic unit 113, and an even parity bit, 1, is obtained.

(3) The parity bit, the report value, and the codeword are written as a transmission word 1_0101011_11001011 on the RAM 12.

(4) It is assumed that a bit error due to a soft error occurs in the data stored in the RAM 12. The bit error occurring at this time is a 3-bit error, and it is assumed that bits at sixth, twelfth, and fifteenth positions (D5, D11, and D14) from the least significant bit are inverted.

(5) The data read from the RAM 12 are input as a received word to the BCH code checker 13. The received word is 1_1100011_11101011.

(6) As illustrated in FIG. 14B, the received word is input to the polynomial arithmetic units 131 and 132, and a syndrome S1:1000, and a syndrome S2:0011 are generated using the polynomial 2 (X4+X+1), and the polynomial 3 (X4+X3+X2+X+1).

(7) The bit error position specifying unit 134 inputs the syndrome S1:1000 and the syndrome S2:0011 as keys to the error determination table (FIGS. 6A to 6C), and acquires a 2-bit error (D2, D8) as a value corresponding to the keys.

(8) The parity checker 133 performs a parity check on the received word. Since the even parity bit of the received word (1_1100011_11101011) is 1, the result of the parity check on the received word indicates “parity error presence.”

(9) The determination result by the error determination table: 2-bit error (D2, D8), and “parity error presence” are input to the controller 135. Based on the fact that the 2-bit error has been detected (FIG. 11, OP6: YES) and there is a parity error (FIG. 11, OP7: YES), the controller 135 confirms a 3-bit error, and notifies the CPU of a device mounted with the error check unit 1 of the 3-bit error (FIG. 11, OP9).

(10) Since the error is a 3-bit error, the bit error correction unit 136 acquires the decoded word from the received word and outputs the decoded word without error correction. Since the received word is 1_1100011_11101011, the decoded word becomes 1100011. The bit error remains in the decoded word. Since the 3-bit error is notified to the CPU, the report value 0101011 is retransmitted by the CPU, and the retransmitted report value 0101011, the codeword, and the parity bit are overwritten on the RAM 12.

As illustrated in FIGS. 14A and 14B, in the case where a 3-bit error occurs, even when the determination result by the error determination table indicates a 2-bit error, and an error is erroneously determined as the 2-bit error, the error check unit 1 may detect the 3-bit error.

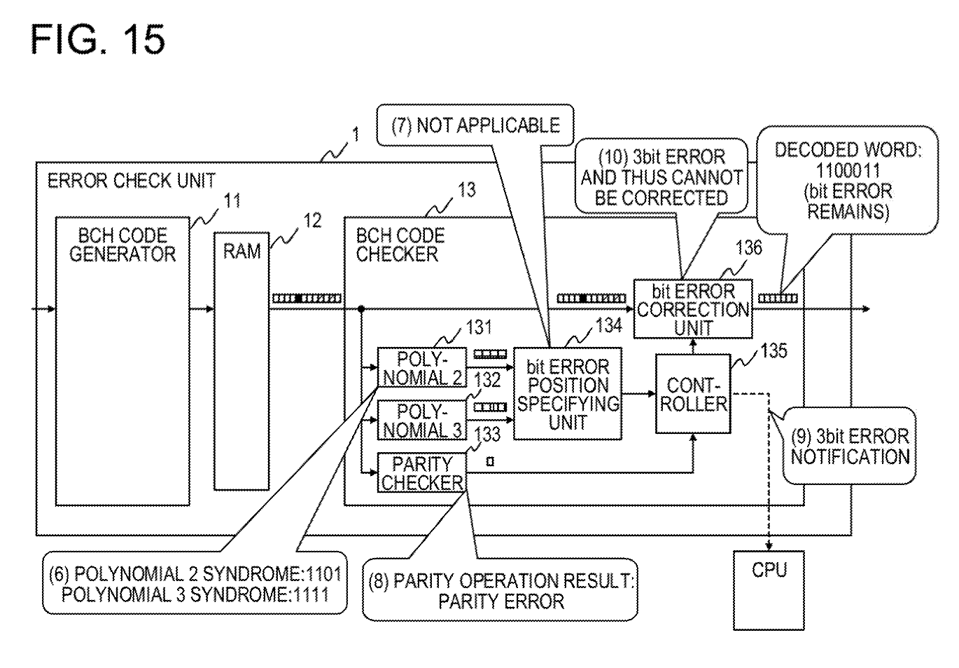

FIG. 15 is a view illustrating an example of a processing when a 3-bit soft error occurs in the RAM 12 of the error check unit 1 according to the specific example. FIG. 15 is a continuation of FIG. 14A. That is, in FIG. 15, it is assumed that a transmission word 1_0101011_11001011 is written on the RAM 12 with respect to a report value 0101011, and a 3-bit error (D6, D11, and D14) occurs in the RAM 12. A received word read from the RAM 12 is 1_1100011_10001011.

(6) The received word is input to the polynomial arithmetic units 131 and 132, and a syndrome S1:1101 and a syndrome S2:1111 are generated using the polynomial 2 (X4+X+1), and the polynomial 3 (X4+X3+X2+X+1).

(7) The bit error position specifying unit 134 inputs the syndrome S1:1101 and the syndrome S2:1111 as keys to the error determination table (FIGS. 6A to 6C), and acquires “not applicable” as a value corresponding to the keys.

(8) The parity checker 133 performs a parity check on the received word. Since the even parity bit of the received word (1_1100011_10001011) is 1, the result of the parity check on the received word indicates “parity error presence.”

(9) The determination result by the error determination table: not applicable and “parity error presence” are input to the controller 135. Based on the fact that the determination result by the error determination table indicates “not applicable” (FIG. 11, OP6: “NO”), the controller 135 detects a 3-bit error, and notifies the CPU of a device mounted with the error check unit 1 of the 3-bit error (FIG. 11, OP9).

(10) Since the error is a 3-bit error, the bit error correction unit 136 acquires the decoded word from the received word and outputs the decoded word without error correction. Since the received word is 1_1100011_10001011, the decoded word becomes 1100011. The bit error remains in the decoded word. In this case as well, since the 3-bit error is notified to the CPU, the report value 0101011 is retransmitted by the CPU, and the retransmitted report value 0101011, the codeword, and the parity bit are overwritten on the RAM 12.

As illustrated in FIG. 15, in the case where a 3-bit error occurs, when the determination result by the error determination table indicates “not applicable,” the error check unit 1 may detect the 3-bit error.

### Operation Effect of First Embodiment

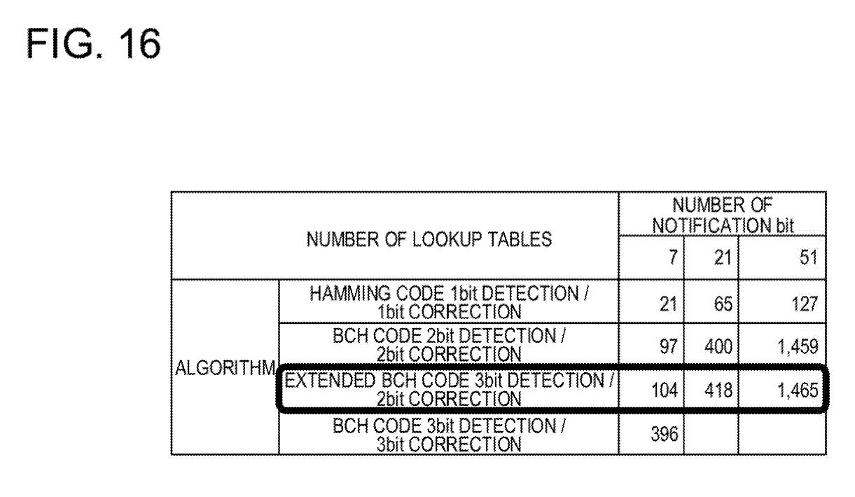

FIG. 16 is an example of a table illustrating a relationship between various algorithms of an error correction code and the number of usages of a lookup table. For example, when the number of bits of the report value is 7, the number of usages of a lookup table is 97 in an error check unit capable of detecting and correcting a 2-bit error (FIG. 2) using a BCH code. In an error check unit 1 capable of detecting a 3-bit error and correcting a 2-bit error using a BCH code, according to the first embodiment, the number of usages of a lookup table is 104. In an error check unit capable of detecting and correcting a 3-bit error using a BCH code (FIG. 3), the number of usages of a lookup table is 396.

The number of usages of a lookup table in the error check unit 1 according to the first embodiment is about one fourth, as compared to the error check unit capable of detecting and correcting a 3-bit error using a BCH code. Although the number of usages of a lookup table is illustrated in FIG. 16, the number of usages of other elements (a flip-flop or the like) within an FPGA in the error check unit 1 according to the first embodiment is also smaller than that in the error check unit capable of detecting and correcting a 3-bit error using a BCH code.

The error check unit 1 according to the first embodiment is a circuit in which a simple parity arithmetic circuit is added to a circuit of the error check unit capable of detecting and correcting a 2-bit error using a BCH code. Accordingly, the error check unit 1 according to the first embodiment may detect an error of up to 3 bits by a circuit scale approximate to a scale of an error check unit capable of detecting and correcting a 2-bit error using a BCH code. When the 2-bit error is detected by the error determination table, it is possible to specify whether the error is a 2-bit error or a 3-bit error by the parity check result, and the detection precision of the 2-bit error and the 3-bit error is improved.

In the first embodiment, the error check unit capable of detecting a 3-bit error and correcting a 2-bit error has been described, but the technique described in the first embodiment is not limited to the 3-bit error detection and the 2-bit error correction. The error check unit provided with the error determination table corresponding to an error code operation capable of detecting and correcting an N-bit error may be added with the parity arithmetic unit 113, the parity checker 133, and the controller 135, thereby implementing an error check unit capable of detecting an N+1 bit error and correcting an N bit error.

### Application Example

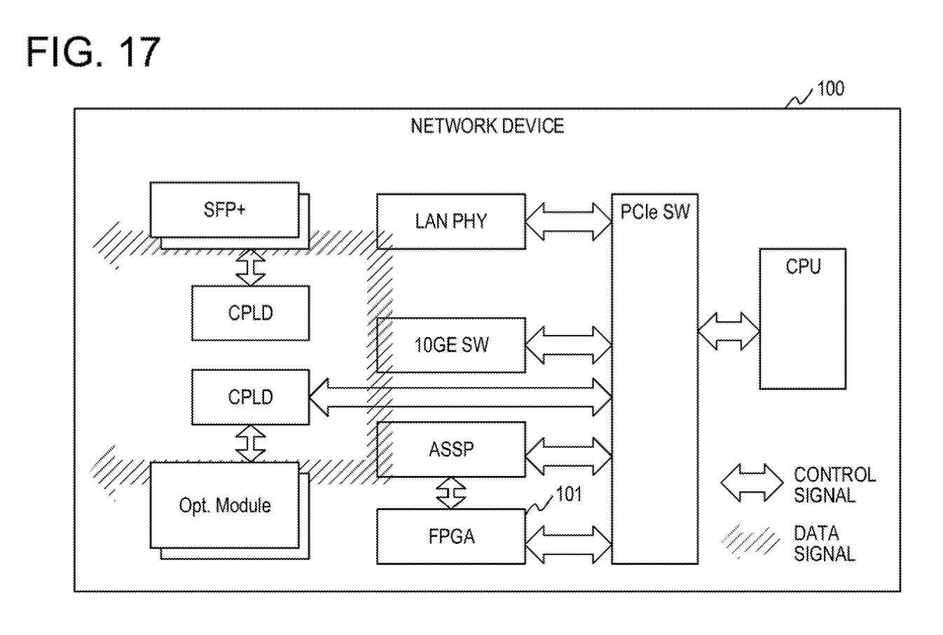

FIG. 17 is a view illustrating an exemplary hardware configuration of a network device mounted with the error check unit 1 according to the first embodiment. The error check unit 1 according to the first embodiment is mounted in, for example, a network device. The network device is, for example, a switch, a router, a gateway, a controller or the like. A network device 100 includes, for example, a CPU, a peripheral component interconnect (PCI) switch, a local area network physical layer (LAN PHY), a 10G Ethernet (registered trademark) switch module, an application specific standard produce (ASSP), a small form-factor pluggable+ (SPF+) module, a complex programmable logic device (CPLD), an optical module, and an FPGA 101. The error check unit 1 according to the first embodiment is formed within the FPGA 101.

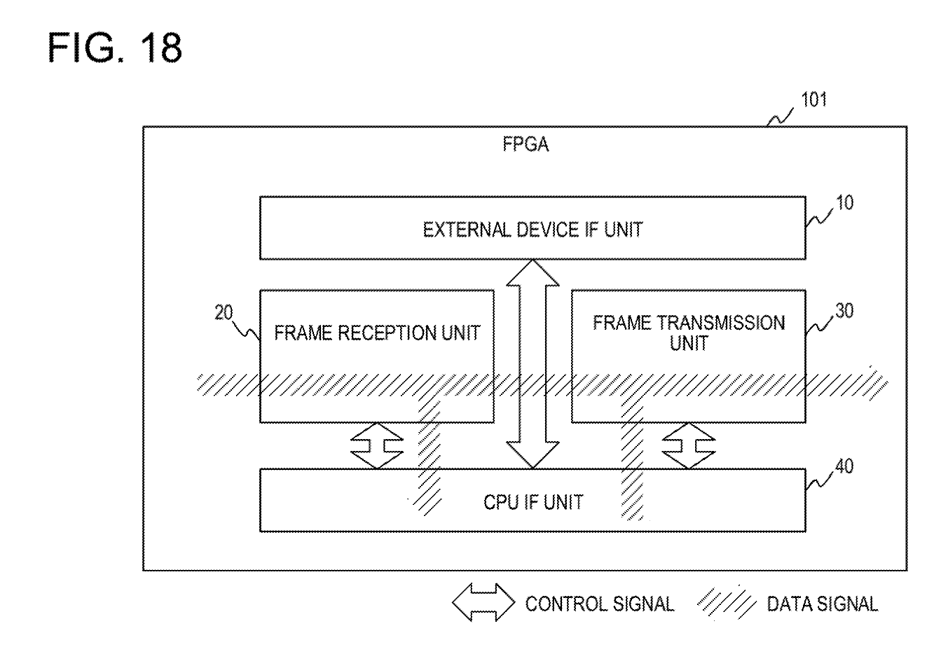

FIG. 18 is an example of a block diagram of the FPGA 101 within the network device 100. The FPGA 101 within the network device 100 performs processes such as quality of service (QoS) and routing. The FPGA 101 includes an external device interface (IF) unit 10, a frame reception unit 20, a frame transmission unit 30, and a CPU interface (IF) unit 40 as functional configurations.

The external device IF unit 10 is an interface with devices other than the CPU. The CPU IF unit 40 is an interface with the CPU. The frame reception unit 20 analyzes a frame received by the network device 100, and performs a processing of notifying the CPU of alarm information. The frame transmission unit 30 receives setting information from the CPU, assembles the information as a frame, and performs an output processing.

The error check unit 1 is provided in, for example, each of the frame reception unit 20 and the frame transmission unit 30.

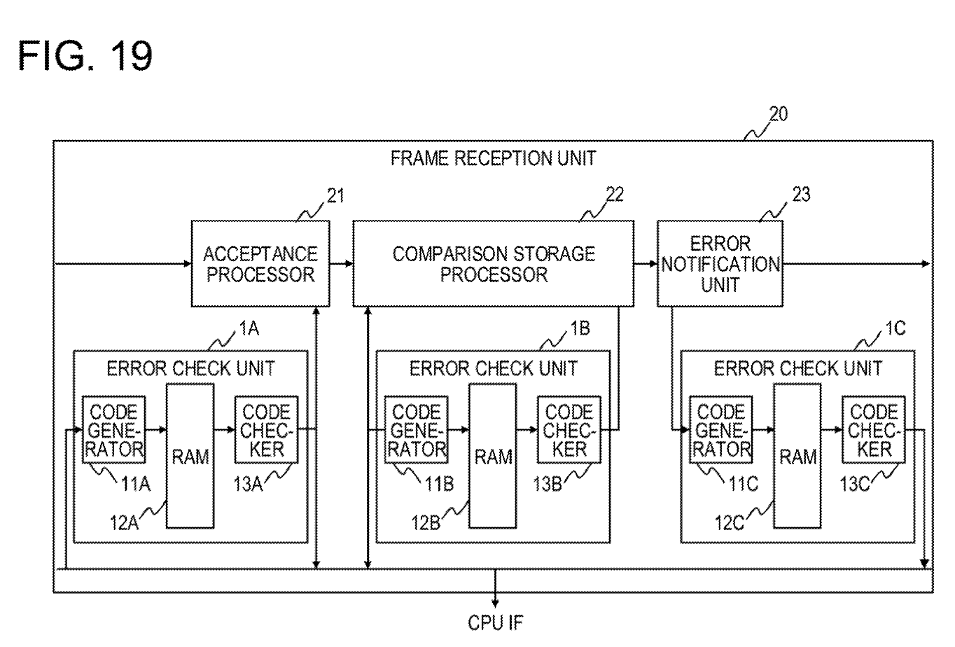

FIG. 19 is an example of a block diagram of the frame reception unit 20. The frame reception unit 20 includes, for example, an acceptance processor 21, a comparison storage processor 22, and an error notification unit 23. The error check unit 1 is provided in each of the acceptance processor 21, the comparison storage processor 22, and the error notification unit 23.

The acceptance processor 21 determines whether an input frame is a processing target, and performs a filtering processing of extracting a frame as the processing target. The acceptance processor 21 is connected to an error check unit 1A. On a RAM 12A within the error check unit 1A, information of the frame as the processing target is written by the CPU. When the frame is input, the acceptance processor 21 reads information of the processing target from the RAM 12A of the error check unit 1A, and performs a filtering processing by comparing the information to the input frame.

The comparison storage processor 22 compares the input frame and a past frame with each other, and stores the input frame when, for example, a change is made. The comparison storage processor 22 is connected to an error check unit 1B. The comparison storage processor 22 uses a RAM 12B of the error check unit 1B as a buffer for storing a frame. When a frame is input, the comparison storage processor 22 reads a past frame from the RAM 12B of the error check unit 1B, and writes the input frame on the RAM 12B of the error check unit 1B when the input frame is changed.

The error notification unit 23 notifies a comparison result obtained by the comparison storage processor 22. The error notification unit 23 is connected to an error check unit 1C. A RAM 12C of the error check unit 1C is used as, for example, a buffer of the comparison result. When the comparison result is input from the comparison storage processor 22, the error notification unit 23 writes the comparison result on the RAM 12C of the error check unit 1C. The CPU reads the comparison result from the RAM 12C of the error check unit 1C, for example, at a predetermined cycle.

The application example of the error check unit 1 according to the first embodiment, as illustrated in FIGS. 17, 18, and 19, is exemplary only, and an application of the error check unit 1 is not limited to the network device. The error check unit 1 according to the first embodiment may be applicable to a device that executes a processing involving writing and reading of data on/from the RAM. The hardware implementing the error check unit 1 is not limited to the FPGA. The error check unit 1 may be implemented by, for example, a large-scale integration (LSI), a CPLD, a hardware processor or the like.

Others

In the first embodiment, descriptions have been made on an error check unit capable of detecting a 3-bit error and correcting and a 2-bit error, but the technique described in the first embodiment is not limited to the 3-bit error detection and the 2-bit error correction. The error check unit provided with the error determination table corresponding to an error code operation capable of detecting and correcting an N-bit error may be added with the parity arithmetic unit 113, the parity checker 133, and the controller 135, thereby implementing an error check unit capable of detecting an N+1 bit error and correcting an N bit error.

In the first embodiment, a BCH code has been described as an example of the error correction code, but error correction codes other than the BCH code may be applied to the technique described in the first embodiment. As the error correction codes applicable to the technique described in the first embodiment, for example, a Hamming code, a Reed-Solomon code (RS code), a Golay code, a convolutional code, and the like may be exemplified.

In the first embodiment, descriptions have been made on the case where a bit error occurs due to a soft error in a RAM, but the technique described in the first embodiment may be applicable to a bit error detection and correction regardless of a factor of occurrence of a bit error. For example, the technique described in the first embodiment may be applicable to the case where a bit error occurs due to a noise during transmission of a communication. When the technique is applied to the bit error caused by the noise during transmission of a communication, for example, the BCH code generator 11 is mounted in an FPGA that performs a transmission processing in a transmitting side device. The BCH code checker 13 is mounted in an FPGA that performs a reception processing in a reception side device.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to an illustrating of the superiority and inferiority of the invention. Although the embodiments of the present invention have been described in detail, it should be understood that the various changes, substitutions, and alterations could be made hereto without departing from the spirit and scope of the invention.

What is claimed is:

1. A data processing system comprising:
a first arithmetic circuit configured to perform a first error correction code operation on an input bit string so as to generate a first bit string including the input bit string and a result of the first error correction code operation;
a parity arithmetic circuit configured to acquire a parity bit of the first bit string;
a second arithmetic circuit configured to perform a second error correction code operation on a second bit string including the first bit string and the parity bit;
a specifying circuit configured to specify a number of at most N-bit error and an error position in the second bit string, based on an operation result of the second error correction code operation on the second bit string, wherein N is an integer larger than 0;
a parity check circuit configured to perform a parity check on the second bit string; and
a control circuit configured to detect a N+1-bit error in the first bit string when the number of bit error specified by the specifying circuit is N and a result of the parity check indicates that there is an error.

2. The data processing system according to claim 1,
wherein the specifying circuit includes an error determination table, and specifies the number of at most N-bit error and the error position in the second bit string by using the error determination table according to the operation result of the second error correction code operation capable of detecting and correcting an N-bit error.

3. The data processing system according to claim 1,
wherein the control circuit detects an N-bit error in the first bit string when the number of bit error specified by the specifying circuit is N, and a result of the parity check indicates that there is no error.

4. A data processing device comprising:
a memory: and
a hardware processor coupled to the memory and the hardware processor configured to:
perform a second error correction code operation on a second bit string that includes a first bit string and a parity bit of the first bit string, the first bit string including a specific bit string and a result of a first error correction code operation on the specific bit string, and the second bit string being read from the memory;
specify a number of at most N-bit error and an error position in the second bit string, based on an operation result of the second error correction code operation on the second bit string, wherein N is an integer larger than 0;
perform a parity check on the second bit string; and
detect a N+1-bit error in the first bit string when the specified number of bit error is N and a result of the parity check indicates that there is an error.

5. The data processing device according to claim 4,
wherein the hardware processor is configured to specify the number of at most N-bit error and the error position in the second bit string read from the memory by using an error determination table according to the operation result of the second error correction code operation capable of detecting and correcting an N-bit error.

6. A data processing device comprising:
a memory; and
at least one hardware processor coupled to the memory and the at least one hardware processor configured to:
perform a first error correction code operation on an input bit string by using a first polynomial so as to generate a first bit string including the input bit string and a result of the first error correction code operation;
acquire a parity bit of the first bit string to be stored in the memory;
perform a second error correction code operation on a second bit string including the first bit string and the parity bit, by using a second polynomial and a third polynomial, the second bit string being read from the memory;
specify a number of at most N-bit error and an error position in the second bit string read from the memory, based on an operation result of the second error correction code operation on the second bit string, wherein N is an integer larger than 0;
perform a parity check on the second bit string read from the memory; and
detect a N+1-bit error in the first bit string read from the memory when the specified number of bit error is N and a result of the parity check indicates that there is an error.

7. The data processing device according to claim 6,
wherein the at least one hardware processor is configured to specify the number of at most N-bit error and the error position in the second bit string read from the memory by using an error determination table according to the operation result of the second error correction code operation capable of detecting and correcting an N-bit error.
